(19) United States
(12) Patent Application Publication
(10) Pub. No.: US 2021/0336096 A1
(43) Pub. Date: Oct. 28, 2021

(54) DISPLAY PANEL AND MANUFACTURING METHOD THEREOF

(71) Applicant: Shenzhen China Star Optoelectronics Semiconductor Display Technology Co., Ltd., Shenzhen, Guangdong (CN)

(72) Inventor: Zhiping Hu, Shenzhen (CN)

(21) Appl. No.: 16/626,747

(22) PCT Filed: Dec. 24, 2019
(86) PCT No.: PCT/CN2019/127714

§ 371 Date: Dec. 26, 2019

(30) Foreign Application Priority Data
Dec. 10, 2019 (CN) 201911258535.8

(51) Int. Cl. H01L 33/50; H01L 33/00; H01L 27/15

(52) U.S. Cl. CPC H01L 33/502; H01L 27/156; H01L 33/005

(57) ABSTRACT

The present invention discloses a display panel and a manufacturing method thereof. The display panel includes: a substrate; blue light-emitting diodes (LEDs) disposed in an array on the substrate and provided with a gap between two neighboring blue LEDs; a light conversion layer having a plurality of quantum dot photoresist units, wherein each of the plurality of quantum dot photoresist units is correspondingly disposed on each of the blue LEDs; and a scattering particle layer disposed in a same layer as the light conversion layer and having a plurality of scattering particle units, wherein each of the plurality of scattering particle units is correspondingly disposed on each of the blue LEDs.

### FIELD OF INVENTION

The present invention is related to the field of display technology, and specifically, to a display panel and a manufacturing method thereof.

### BACKGROUND OF INVENTION

Quantum dot materials, as a core of micro display technology, have attracted widespread attention because of their low costs and excellent optical characteristics. Compared with organic light-emitting materials, advantages of the quantum dot materials include: ability to be produce by solution synthesis, simple production, low costs, easy spectrum control, and high color purity. Therefore, quantum dots can be used for color conversion, replacing traditional color filters.

Because light-emitting materials of inorganic micro light-emitting diodes (LEDs) have advantages of good stability and high brightness, and their pixel size can be reduced to a nanometer level, inorganic micro LEDs have great application potential in the field of display technology. Compared with organic light-emitting diodes (OLEDs), the biggest advantage of the inorganic micro LEDs is that a lifespan of blue LEDs is very stable. Nevertheless, the biggest difficulty of the inorganic micro LEDs is mass transfer of different color LEDs. Red LEDs, green LEDs, and blue LEDs need to be disposed on different substrates and respectively fixed on a driving substrate by picking, placing, and attaching.

In order to overcome the technical difficulty of the mass transfer of the three color LEDs from different substrates, there is a technique that blue LEDs can be used as a backlight source, and red quantum dots and green quantum dots can be used as a color conversion layer to form the three primary colors of red, green, and blue to achieve a full color display. However, the difficulty of this technique is how to pattern quantum dots and combine them with blue LEDs.

Therefore, it is necessary to develop a new manufacturing method of a display panel to overcome the defects of the prior art.

### SUMMARY OF INVENTION

A purpose of the present invention is to provide a display panel capable of solving the problem of how to pattern quantum dots in a display panel in the prior art.

In order to achieve the above purpose, the present invention provides a display panel including: a substrate; blue light-emitting diodes (LEDs) disposed in an array on the substrate and provided with a gap between two neighboring blue LEDs; a passivation layer disposed on the substrate and filled in the gap between the two neighboring blue LEDs; a first black photoresist disposed on the passivation layer; a light conversion layer disposed in a same layer as the first black photoresist and having a plurality of quantum dot photoresist units, wherein each of the plurality of quantum dot photoresist units is correspondingly disposed on each of the blue LEDs; and a scattering particle layer disposed in a same layer as the light conversion layer and having a plurality of scattering particle units, wherein each of the plurality of scattering particle units is correspondingly disposed on each of the blue LEDs. The first black photoresist is used to block an excitation of the plurality of quantum dot photoresist units by an emission of the blue LEDs to reduce a crosstalk phenomenon.

Furthermore, in other embodiments, the plurality of quantum dot photoresist units include red quantum dot photoresist units and green quantum dot photoresist units, and the light conversion layer includes a red quantum dot photoresist layer and a green quantum dot photoresist layer.

Furthermore, in other embodiments, the display panel further includes a plurality of pixel units, and each of the plurality of pixel units includes one of the red quantum dot photoresist units, one of the green quantum dot photoresist units, and one of the plurality of scattering particle units. Filling of the scattering particle layer can expand viewing angles of blue sub-pixels.

Furthermore, in other embodiments, the display panel further includes a color filter disposed on the light conversion layer and the first black photoresist; the color filter includes a second black photoresist disposed on the first black photoresist and a color resist layer disposed in a same layer as the second black photoresist; and the color resist layer includes red color resists, green color resists, and blue color resists, wherein the red color resists correspond to the red quantum dot photoresist units, the green color resists correspond to the green quantum dot photoresist units, and the blue color resists correspond to the plurality of scattering particle units. The color filter can filter out blue light that is not absorbed by the plurality of quantum dot photoresist units.

Furthermore, in other embodiments, a thickness of the passivation layer is greater than or equal to a thickness of the blue LEDs.

The present invention further provides a manufacturing method of the display panel. The manufacturing method includes the steps of: providing a substrate; forming blue light-emitting diodes (LEDs) in an array on the substrate with a gap between two neighboring blue LEDs; forming a passivation layer on the substrate and filling the gap between the two neighboring blue LEDs; forming a first black photoresist on the passivation layer; forming a light conversion layer in a same layer as the first black photoresist, wherein the light conversion layer has a plurality of quantum dot photoresist units, and each of the plurality of quantum dot photoresist units is correspondingly disposed on each of the blue LEDs; and forming a scattering particle layer in the same layer as the first black photoresist, wherein the scattering particle layer has a plurality of scattering particle units, and each of the plurality of scattering particle units is correspondingly disposed on each of the blue LEDs.

Furthermore, in other embodiments, the step of forming a light conversion layer in a same layer as the first black photoresist includes the steps of: coating a green quantum dot photoresist in a gap of the first black photoresist and forming a patterned green quantum dot photoresist layer after exposure and development; and coating a red quantum dot photoresist in the gap of the first black photoresist and forming a patterned red quantum dot photoresist layer after exposure and development.

Furthermore, in other embodiments, forming a color filter on the light conversion layer after forming the scattering particle layer.

Furthermore, in other embodiments, the passivation layer is formed by a chemical vapor deposition process.

Furthermore, in other embodiments, the scattering particle layer is formed by an inkjet printing process or a photolithography process.

Furthermore, in other embodiments, the first black photoresist is formed by a coating process.

Compared to the prior art, the present invention provides the display panel and the manufacturing method thereof, which uses the blue LEDs as a backlight source, uses the quantum dot materials as photoresists, and uses conventional photolithography technology to implement patterning red and green quantum dot film layers. Then, the blue LEDs are combined with them, and red and green quantum dots are excited by the blue LEDs, which can be used as red and green sub-pixels to form the three primary colors of red, green, and blue to achieve a full color display. The manufacturing method of the present invention is simple and can reduce costs, and the display panel can be compatible with color filters to produce a high-resolution panel.

### DESCRIPTION OF DRAWINGS

The following describes specific embodiments of the present invention in detail with reference to the accompanying drawings, which will make technical solutions and other beneficial effects of the present invention obvious.

FIG. 1 is a structural diagram of a display panel according to an embodiment.

FIG. 2 is a flowchart of a manufacturing method of the display panel according to the embodiment.

FIG. 3 is a structural diagram of step S2 of the manufacturing method of the display panel according to the embodiment.

FIG. 4 is a structural diagram of step S3 of the manufacturing method of the display panel according to the embodiment.

FIG. 5 is a structural diagram of step S4 of the manufacturing method of the display panel according to the embodiment.

FIG. 6 is a structural diagram of step S51 of the manufacturing method of the display panel according to the embodiment.

FIG. 7 is a structural diagram of step S52 of the manufacturing method of the display panel according to the embodiment.

FIG. 8 is a structural diagram of step S53 of the manufacturing method of the display panel according to the embodiment.

FIG. 9 is a structural diagram of step S54 of the manufacturing method of the display panel according to the embodiment.

FIG. 10 is a structural diagram of step S6 of the manufacturing method of the display panel according to the embodiment.

FIG. 11 is a structural diagram of step S7 of the manufacturing method of the display panel according to the embodiment.

### REFERENCE SIGNS

display panel 100, substrate 110, blue LED 120, passivation layer 130, first black photoresist 140, light conversion layer 150, green quantum dot photoresist layer 151, green quantum dot photoresist 1511, red quantum dot photoresist layer 152, red quantum dot photoresist 1521, scattering particle layer 160, color filter 170, second black photoresist 171, color resist layer 172, red color resists 1721, green color resists 1722, and blue color resists 1723.

### DETAILED DESCRIPTION OF PREFERRED EMBODIMENTS

To further explain the technical means and effect of the present invention, the following refers to embodiments and drawings for detailed description. Obviously, the described embodiments are only for some embodiments of the present invention, instead of all embodiments. Based on the embodiments of the present invention, all other embodiments obtained by those skilled in the art without creative work fall into a protection scope of the present invention.

Directional terms mentioned in the present invention, such as upper, lower, front, rear, left, right, in, out, side, etc., only refer to directions in the accompanying drawings. Thus, the adoption of directional terms is used to describe and understand the present invention, but not to limit the present invention. In addition, the terms “first” and “second” are merely used for illustrative purposes only, but are not to be construed as indicating or imposing a relative importance or implicitly indicating the number of technical features indicated. Thus, a feature that defines “first” or “second” may expressly or implicitly include one or more of the features. In the description of the present invention, the meaning of “plural” is two or more, unless otherwise specified.

In the present invention, unless otherwise specifically stated and defined, terms “connected”, “fixed”, etc. should be interpreted expansively. For example, “fixed” may be fixed connection, also may be detachable connection, or integration; may be mechanical connection, also may be electrical connection; may be direct connection, also may be indirect connection through an intermediate, and may be internal communication between two elements or interaction of two elements, unless otherwise specifically defined. The ordinary skill in this field can understand the specific implication of the above terms in the present disclosure according to specific conditions.

In the present invention, unless otherwise specifically stated and defined, a structure in which a first feature is “on” or “below” a second feature may include an embodiment in which the first feature is in direct contact with the second feature, and may also include an embodiment in which the first feature and the second feature are not in direct contact with each other, but are contacted via an additional feature formed therebetween. Furthermore, a first feature “on,” “above,” or “on top of” a second feature may include an embodiment in which the first feature is right or obliquely “on,” “above,” or “on top of” the second feature, or just means that the first feature is at a height higher than that of the second feature; while a first feature “below,” “under,” or “on bottom of” a second feature may include an embodiment in which the first feature is right or obliquely “below,” “under,” or “on bottom of” the second feature, or just means that the first feature is at a height lower than that of the second feature.

Various embodiments or examples are provided here below to implement the different structures of the present invention. To simplify the disclosure of the present invention, description of the components and arrangements of specific examples is given below. Of course, they are only illustrative and not limiting the present invention. Moreover, in the present invention, reference numbers and/or letters may be repeated in different embodiments. Such repetition is for the purposes of simplification and clearness, and does not denote the relationship between respective embodiments and/or arrangements being discussed. Furthermore, the present invention provides various examples for specific process and materials. However, it is obvious for a person of ordinary skill in the art that other processes and/or materials may alternatively be utilized.

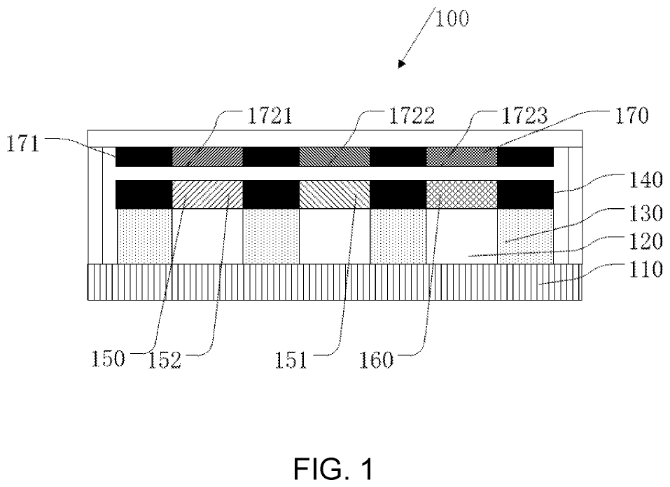

As shown in FIG. 1, a display panel 100 provided by an embodiment of the present invention includes a substrate 110, blue light-emitting diodes (LEDs) 120, a passivation layer 130, a first black photoresist 140, a light conversion layer 150, and a scattering particle layer 160.

The blue LEDs 120 are disposed in an array on the substrate 110 and provided with a gap between two neighboring blue LEDs 120. The passivation layer 130 is disposed on the substrate 110 and filled in the gap between the two neighboring blue LEDs 120. A thickness of the passivation layer 130 is equal to a thickness of the blue LEDs 120, and in another embodiment, the thickness of the passivation layer 130 can be greater than the thickness of the blue LEDs 120.

The first black photoresist 140 is disposed on the passivation layer 130. The light conversion layer 150 is disposed in a same layer as the first black photoresist 140 and has a plurality of quantum dot photoresist units. Each of the plurality of quantum dot photoresist units is correspondingly disposed on each of the blue LEDs 120. The scattering particle layer 160 is disposed in a same layer as the light conversion layer 150 and has a plurality of scattering particle units. Each of the plurality of scattering particle units is correspondingly disposed on each of the blue LEDs 120.

The first black photoresist 140 is used to block an excitation of the plurality of quantum dot photoresist units by an emission of the blue LEDs 120 to reduce a crosstalk phenomenon.

The plurality of quantum dot photoresist units include red quantum dot photoresist units and green quantum dot photoresist units. The light conversion layer 150 includes a red quantum dot photoresist layer 152 and a green quantum dot photoresist layer 151.

The display panel 100 further includes a plurality of pixel units. Each of the plurality of pixel units includes one of the red quantum dot photoresist units, one of the green quantum dot photoresist units, and one of the plurality of scattering particle units. Filling of the scattering particle layer 160 can expand viewing angles of blue sub-pixels.

The display panel 100 further includes a color filter 170 disposed on the light conversion layer 150 and the first black photoresist 140. The color filter 170 includes a second black photoresist 171 disposed on the first black photoresist 140 and a color resist layer 172 disposed in a same layer as the second black photoresist 171. The color resist layer 172 includes red color resists 1721, green color resists 1722, and blue color resists 1723. The red color resists 1721 correspond to the red quantum dot photoresist units. The green color resists 1722 correspond to the green quantum dot photoresist units. The blue color resists 1723 correspond to the plurality of scattering particle units. The color filter 170 can filter out blue light that is not absorbed by the plurality of quantum dot photoresist units.

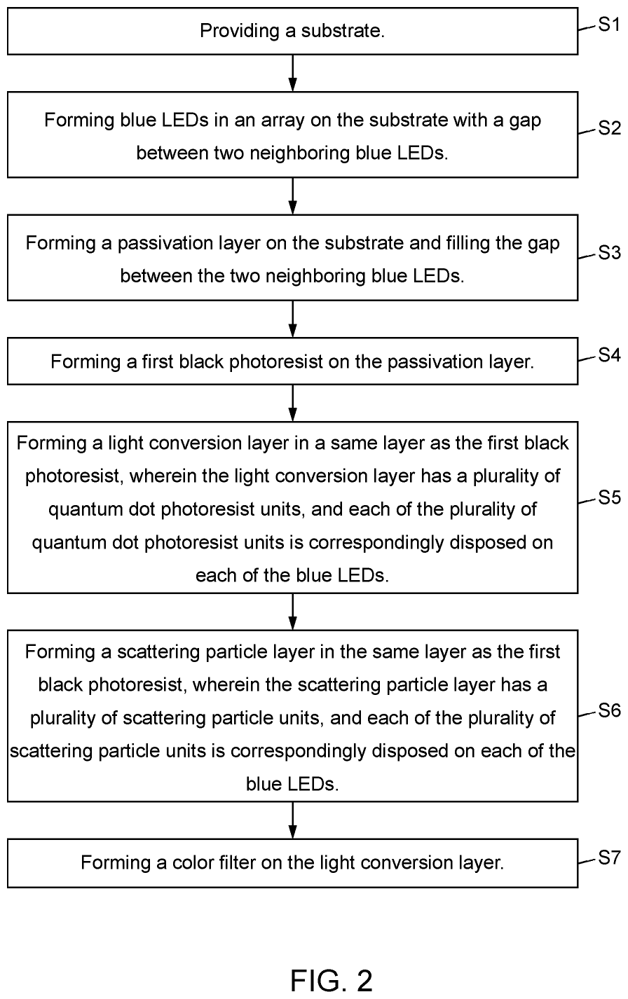

The present invention further provides a manufacturing method of the display panel 100. As shown in FIG. 2, which is a flowchart of the manufacturing method of the display panel 100 according to the embodiment, the manufacturing method includes steps S1 to S7.

Step S1: providing a substrate 110.

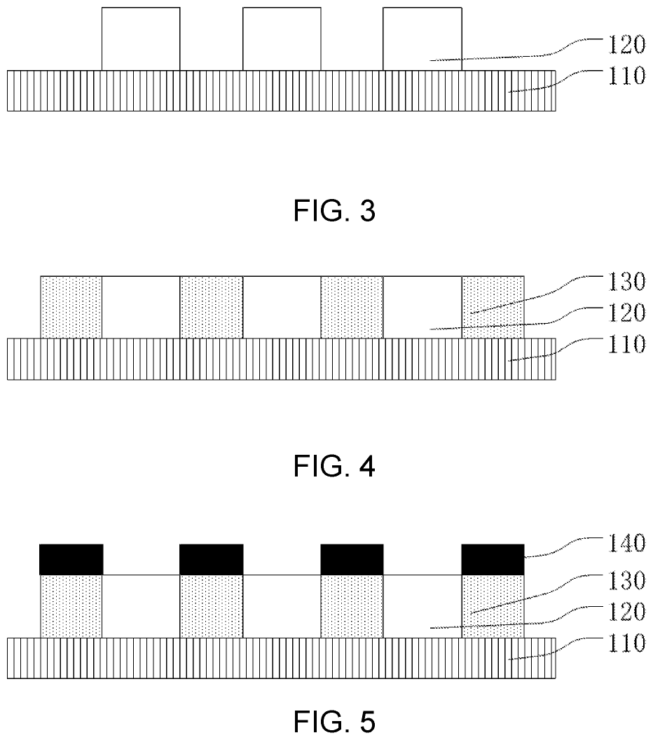

Step S2: forming blue light-emitting diodes (LEDs) 120 in an array on the substrate 110. A gap is provided between two neighboring blue LEDs 120. Please refer to FIG. 3, which is a structural diagram of the step S2 of the manufacturing method of the display panel according to the embodiment.

Step S3: forming a passivation layer 130 on the substrate 110 and filling the gap between the two neighboring blue LEDs 120. Please refer to FIG. 4, which is a structural diagram of the step S3 of the manufacturing method of the display panel according to the embodiment. The passivation layer 130 is formed by a chemical vapor deposition process.

Step S4: forming a first black photoresist 140 on the passivation layer 130. Please refer to FIG. 5, which is a structural diagram of the step S4 of the manufacturing method of the display panel according to the embodiment.

Step S5: forming a light conversion layer 150 in a same layer as the first black photoresist 140. The light conversion layer 150 has a plurality of quantum dot photoresist units, and each of the plurality of quantum dot photoresist units is correspondingly disposed on each of the blue LEDs 120. Specifically, the step S5 further includes steps S51 to S54.

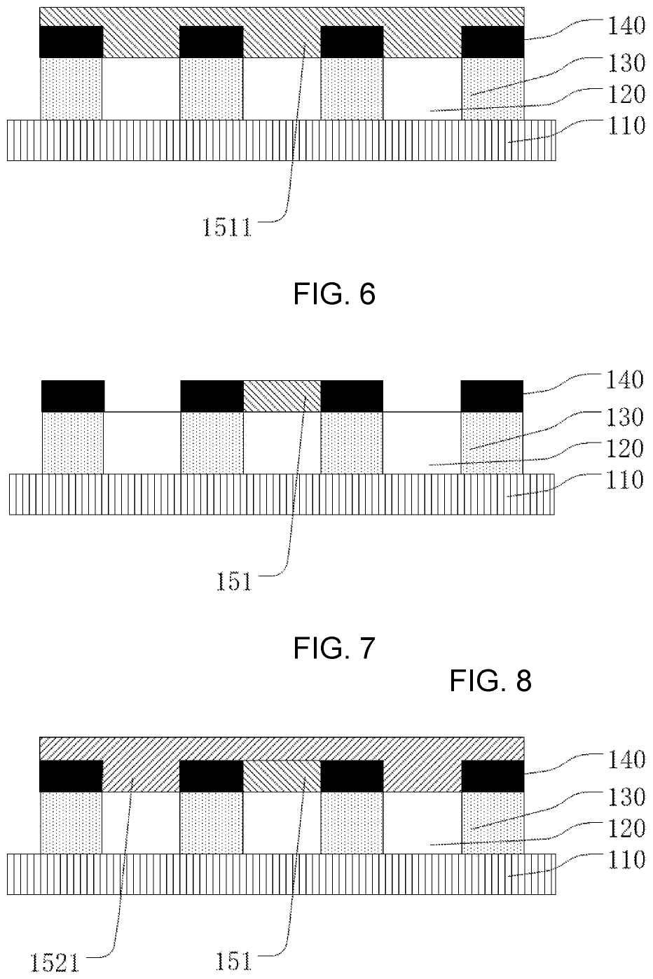

Step S51: coating a green quantum dot photoresist 1511 in a gap of the first black photoresist 140. Please refer to FIG. 6, which is a structural diagram of the step S51 of the manufacturing method of the display panel according to the embodiment.

Step S52: forming a patterned green quantum dot photoresist layer 151 after the green quantum dot photoresist 1511 is exposed and developed. Please refer to FIG. 7, which is a structural diagram of the step S52 of the manufacturing method of the display panel according to the embodiment.

Step S53: coating a red quantum dot photoresist 1521 in the gap of the first black photoresist 140. Please refer to FIG. 8, which is a structural diagram of the step S53 of the manufacturing method of the display panel according to the embodiment.

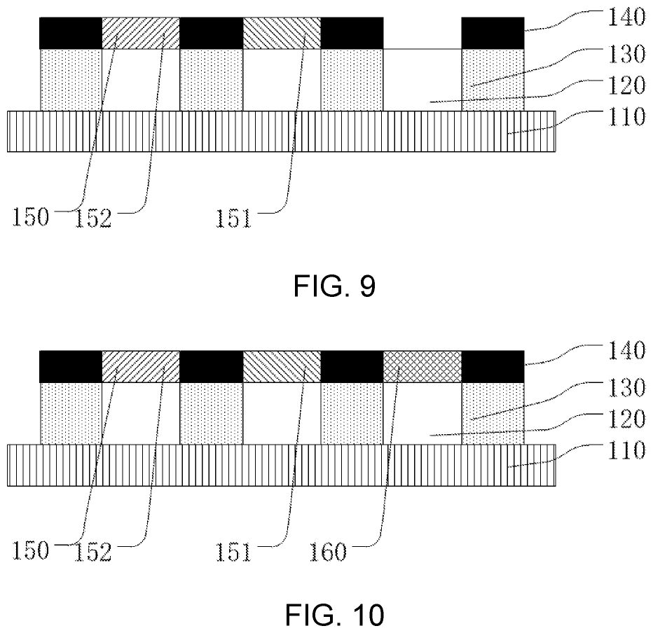

Step S54: forming a patterned red quantum dot photoresist layer 152 after the red quantum dot photoresist 1521 is exposed and developed. Please refer to FIG. 9, which is a structural diagram of the step S54 of the manufacturing method of the display panel according to the embodiment.

Step S6: forming a scattering particle layer 160 in the same layer as the first black photoresist 140. The scattering particle layer 160 has a plurality of scattering particle units. Each of the plurality of scattering particle units is correspondingly disposed on each of the blue LEDs 120. The scattering particle layer 160 is formed by an inkjet printing process or a photolithography process. Please refer to FIG. 10, which is a structural diagram of the step S6 of the manufacturing method of the display panel according to the embodiment.

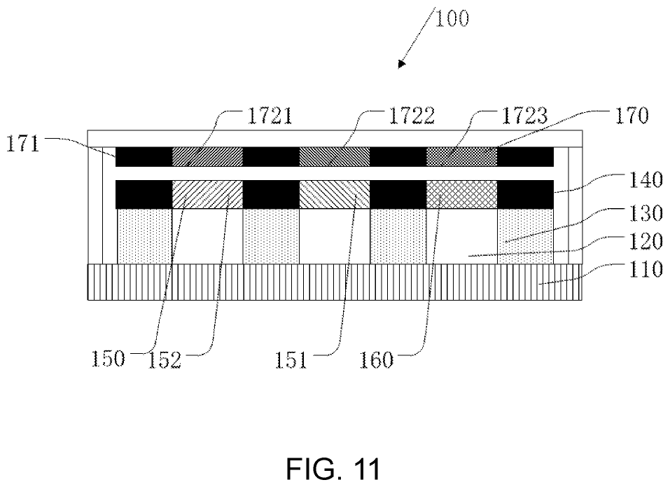

Step S7: forming a color filter 170 on the light conversion layer 150. Please refer to FIG. 11, which is a structural diagram of the step S7 of the manufacturing method of the display panel according to the embodiment.

The present invention provides the display panel and the manufacturing method thereof, which uses the blue LEDs as a backlight source, uses the quantum dot materials as photoresists, and uses conventional photolithography technology to implement patterning red and green quantum dot film layers. Then, the blue LEDs are combined with them, and red and green quantum dots are excited by the blue LEDs, which can be used as red and green sub-pixels to form the three primary colors of red, green, and blue to achieve a full color display. The manufacturing method of the present invention is simple and can reduce costs, and the display panel can be compatible with color filters to produce a high-resolution panel.

In the above embodiments, the description of each embodiment has its own emphasis. For a part that is not described in detail in one embodiment, reference may be made to related descriptions in other embodiments.

Although the present invention has been disclosed above by the preferred embodiments, the preferred embodiments are not intended to limit the invention. One of ordinary skill in the art, without departing from the spirit and scope of the present invention, can make various modifications and variations of the present invention. Therefore, the scope of the claims to define the scope of equivalents.

What is claimed is:

1. A display panel, comprising:
a substrate;
blue light-emitting diodes (LEDs) disposed in an array on the substrate and provided with a gap between two neighboring blue LEDs;
a passivation layer disposed on the substrate and filled in the gap between the two neighboring blue LEDs;
a first black photoresist disposed on the passivation layer;
a light conversion layer disposed in a same layer as the first black photoresist and having a plurality of quantum dot photoresist units, wherein each of the plurality of quantum dot photoresist units is correspondingly disposed on each of the blue LEDs; and
a scattering particle layer disposed in a same layer as the light conversion layer and having a plurality of scattering particle units, wherein each of the plurality of scattering particle units is correspondingly disposed on each of the blue LEDs.

2. The display panel as claimed in claim 1, wherein the plurality of quantum dot photoresist units comprise red quantum dot photoresist units and green quantum dot photoresist units, and the light conversion layer comprises a red quantum dot photoresist layer and a green quantum dot photoresist layer.

3. The display panel as claimed in claim 2, wherein the display panel further comprises a plurality of pixel units, and each of the plurality of pixel units comprises one of the red quantum dot photoresist units, one of the green quantum dot photoresist units, and one of the plurality of scattering particle units.

4. The display panel as claimed in claim 2, wherein the display panel further comprises a color filter disposed on the light conversion layer and the first black photoresist;
the color filter comprises a second black photoresist disposed on the first black photoresist and a color resist layer disposed in a same layer as the second black photoresist; and
the color resist layer comprises red color resists, green color resists, and blue color resists, wherein the red color resists correspond to the red quantum dot photoresist units, the green color resists correspond to the green quantum dot photoresist units, and the blue color resists correspond to the plurality of scattering particle units.

5. The display panel as claimed in claim 1, wherein a thickness of the passivation layer is greater than or equal to a thickness of the blue LEDs.

6. A manufacturing method of the display panel as claimed in claim 1, comprising the steps of:
providing a substrate;
forming blue light-emitting diodes (LEDs) in an array on the substrate with a gap between two neighboring blue LEDs;
forming a passivation layer on the substrate and filling the gap between the two neighboring blue LEDs;
forming a first black photoresist on the passivation layer;
forming a light conversion layer in a same layer as the first black photoresist, wherein the light conversion layer has a plurality of quantum dot photoresist units, and each of the plurality of quantum dot photoresist units is correspondingly disposed on each of the blue LEDs; and
forming a scattering particle layer in the same layer as the first black photoresist, wherein the scattering particle layer has a plurality of scattering particle units, and each of the plurality of scattering particle units is correspondingly disposed on each of the blue LEDs.

7. The manufacturing method as claimed in claim 6, wherein the step of forming the light conversion layer in the same layer as the first black photoresist comprises the steps of:
coating a green quantum dot photoresist in a gap of the first black photoresist and forming a patterned green quantum dot photoresist layer after exposure and development; and
coating a red quantum dot photoresist in the gap of the first black photoresist and forming a patterned red quantum dot photoresist layer after exposure and development.

8. The manufacturing method as claimed in claim 6, wherein the passivation layer is formed by a chemical vapor deposition process.

9. The manufacturing method as claimed in claim 6, wherein the scattering particle layer is formed by an inkjet printing process or a photolithography process.

10. The manufacturing method as claimed in claim 6, wherein the first black photoresist is formed by a coating process.

11. The manufacturing method as claimed in claim 6, wherein the plurality of quantum dot photoresist units comprise red quantum dot photoresist units and green quantum dot photoresist units, and the light conversion layer comprises a red quantum dot photoresist layer and a green quantum dot photoresist layer.

12. The manufacturing method as claimed in claim 11, wherein the display panel further comprises a plurality of pixel units, and each of the plurality of pixel units comprises one of the red quantum dot photoresist units, one of the green quantum dot photoresist units, and one of the plurality of scattering particle units.

13. The manufacturing method as claimed in claim 11, wherein the display panel further comprises a color filter disposed on the light conversion layer and the first black photoresist;
the color filter comprises a second black photoresist disposed on the first black photoresist and a color resist layer disposed in a same layer as the second black photoresist; and
the color resist layer comprises red color resists, green color resists, and blue color resists, wherein the red color resists correspond to the red quantum dot photoresist units, the green color resists correspond to the green quantum dot photoresist units, and the blue color resists correspond to the plurality of scattering particle units.

14. The manufacturing method as claimed in claim 6, wherein a thickness of the passivation layer is greater than or equal to a thickness of the blue LEDs.
